(19) United States
(12) Patent Application Publication
(10) Pub. No.: US 2007/0146088 A1
(43) Pub. Date: Jun. 28, 2007

(54) OSCILLATION CIRCUIT AND A SEMICONDUCTOR CIRCUIT DEVICE HAVING THE OSCILLATION CIRCUIT

(76) Inventors: Izumi ARAI, Tokyo (JP); Kazuaki Hori, Tokyo (JP)

Correspondence Address: MATTINGLY, STANGER, MALUR & BRUNDIDGE, P.C., 1800 DIAGONAL ROAD, SUITE 370, ALEXANDRIA, VA, 22314, US

(21) Appl. No.: 11/614,634

(22) Filed: Dec. 21, 2006

(30) Foreign Application Priority Data
Dec. 26, 2005 (JP) 2005-372705

(51) Int. Cl. H03B 5/08

(52) U.S. Cl. 331/167

(57) ABSTRACT

There is provided an LC resonance type oscillation circuit with a wide frequency variable range with a small variation of Q and capable of reducing a chip size due to no external parts required, and a communication semiconductor circuit device (high-frequency IC) having the oscillation circuit. In the LC resonance type oscillation circuit, a capacitance element and a switch element are connected in parallel between both terminals of a secondary side inductance element which is placed facing an inductance element constituting the LC resonance circuit and is connected by mutual induction to the inductance element. It is designed so that an equivalent inductance increases as the capacitance element is connected between the both terminals of the secondary side inductance element in a state where the switch element is turned OFF, and that the equivalent inductance decreases as the both terminals of the secondary side inductance element are short-circuited in a state where the switch element is turned ON.

### CROSS-REFERENCE TO RELATED APPLICATION

The present application claims priority from Japanese patent application No. 2005-372705 filed on Dec. 26, 2005, the content of which is hereby incorporated by reference into this application.

### BACKGROUND OF THE INVENTION

The present invention relates to a technology effectively applicable to a voltage controlled oscillator (VCO) and an LC resonance voltage controlled oscillator. It also relates to a technology effectively applicable to a voltage controlled oscillator included in a communication semiconductor circuit device constituting a wireless communication device, such as, for example, a cellular phone, to generate an oscillation signal of a wide frequency range used for modulation and demodulation of transmission and reception signals.

In a wireless communication device such as a cellular phone, there is used a communication semiconductor circuit device (hereinafter referred to as a high-frequency IC) having a voltage controlled oscillator (hereinafter referred to as a VCO) that generates a local oscillation signal of a predetermined frequency to be synthesized with a transmission signal and a reception signal for modulation and demodulation, to modulate the transmission signal and demodulating the reception signal.

Recently, a cellular phone of a dual-band system that can handle the signal of two frequency bands such as GSM (Global System for Mobile Communication) and DCS (Digital Cellular System), and a cellular phone based on WCDMA (Wideband Code Division Multiple Access) technology with a wide frequency band, have become widely used in the field of cellular phones. Along with the development in this field, there has been a demand for the VCO that generates the local oscillation signal to be able to perform an oscillation operation in a wider frequency range.

The VCO having been put into practical use was not the one that can sufficiently meet the frequency range required by the WCDMA cellular phone. Thus, the conventional high-frequency IC used for the WCDMA cellular phone has been often provided with two or more VCOs respectively for transmission and reception. The cellular phone has a high demand for a reduction in size and weight. Not only the reduction of the chip size of the IC but also the reduction of the number of external parts and downsizing are important issues to meet such a demand.

The conventional high-frequency IC used for the WCDMA cellular phone uses an LC resonance type VCO, for which it is necessary to have elements, such as an inductor and a varactor diode, occupying a relatively large area when integrated on-chip. Further, the use of external parts as these elements leads to an increase of the number of external terminals. Thus, it has been difficult to reduce the chip size in the conventional LC resonance type VCO. Incidentally, there are inventions relating to the LC resonance type VCO with a wide frequency range, which are described, for example, in Japanese Unexamined Patent Publication No. 2002-151953 and in Japanese Patent Application 2004-324657 that the applicant has submitted.

Of the inventions, as shown in FIG. 1A, the VCO described in Japanese Unexamined Patent Publication No. 2002-151953 is provided with a secondary inductor L2 placed in parallel to an inductor L1 constituting an LC resonance circuit, and a switch SW1 for making the connection between both terminals thereof into a short-circuit or cut-off state. In this ways it is designed to realize a wide frequency range by switching an inductance value seen from the primary side with the switch SW1 turned ON or OFF.

Further, as shown in FIG. 1B, the VCO described in the earlier application of the applicant is provided with a secondary side inductor L2 placed in parallel to an inductor L1 constituting an LC resonance circuit, and a switch SW1 and capacity C0 that are serially connected between both terminals thereof. In this way it is designed to switch an inductance value seen from the primary side with the switch SW1 turned ON or OFF.

### SUMMARY OF THE INVENTION

The present inventors have focused attention on the variation of Q (Quality-factor) of the LC resonance circuit in accordance with the switching of the inductance value. When Q decreases in the LC resonance circuit, the oscillation output amplitude decreases and the Carrier-to-Noise ratio (CNR) degrades. Thus it is necessary to give sufficient consideration to the reduction of Q. With the VCO described in Japanese Unexamined Patent Publication No. 2002-151953, when the switch SW1 is turned ON and the inductance value is switched, the oscillation frequency becomes higher than in the SW1 OFF state while Q largely decreases as indicated by the dashed line A in FIG. 2.

With the VCO described in the earlier application of the applicant, a problem has been found that when the switch SW1 turned ON and the inductance value is switched, the oscillation frequency becomes lower than in the SW1 OFF state while Q largely decreases as indicted by the dotted line B in FIG. 2. Incidentally, the curves A, B in FIG. 2 show the case where the values of the secondary side inductor L2 and capacitance element C0 are set so that the frequency is changed by 0.6 GHz with the switch SW1 turned ON and OFF, by setting an oscillation frequency f0 in the state where the both terminals of the secondary side inductor L2 are open, namely, the inductance value of the primary side inductor L1 is only present, as a target frequency.

It is desirable to provide an LC resonance type oscillation circuit with a wide frequency variable range and a small variation of Q, and a communication semiconductor circuit device (high-frequency IC) having the oscillation circuit.

It is further desirable to provide an LC resonance type oscillation circuit with a wide frequency variable range and capable of reducing the chip size due to no external parts required, and a communication semiconductor circuit device (high-frequency IC) having the oscillation circuit.

The above and other objects and new features of the present invention will be apparent from the descriptions of the present specification and the accompanying drawings.

The representative of the invention to be disclosed herein will be briefly summarized in the following.

That is in an oscillation circuit having a tank circuit including an inductance element, a capacitance element and a switch element are connected in parallel between both terminals of a secondary side inductance element which is placed in parallel to and connected by mutual induction to the inductance element constituting the tank circuit. It has been designed so that the equivalent inductance increases as the capacitance element is connected between the both terminals of the secondary side inductance element with the switch element turned OFF, and the equivalent inductance decreases as the both terminals of the secondary side inductance element are short-circuited with the switch element turned ON. In other words, it has been designed to switch the equivalent inductance so as to perform an oscillation operation either in a first state of higher frequency or in a second state of lower frequency, comparing based on the oscillation frequency in the state where the both terminals of the secondary side inductance element are open.

According to the above described method, since not the both terminals of the secondary side inductance element are open, the oscillation operation is not performed at the maximal point of Q, and Q is not largely changed between the ON state and OFF state of the switch element. In other words, when the frequency variable range is made uniform in the VCO, the difference of the Q values is smaller between in the state where the equivalent inductance is large and in the state where the equivalent inductance is small, as compared to the VCO described in Japanese Unexamined Patent Publication No. 2002-151953 where the switch is provided in parallel to the secondary side inductance to make the connection between the both terminals into a short-circuit or cut-off state, or compared to the VCO described in the earlier application where the switch element and the capacitance element are serially connected between the both terminals of the secondary side inductance element. As a result, it is possible to obtain an LC resonance type VCO with a larger oscillation output amplitude and better CNR than the conventional VCO.

Here, it is desirable to set so that the Q value of the tank circuit including a negative resistance circuit and a variable inductance circuit in the ON state of the secondary side switch element and the Q value of the tank circuit in the OFF state of the switch element are substantially equal to each other. This makes it possible to obtain an oscillation circuit where the Q value is less variable and an average reduction of the Q value is small. However, the calculation of the Q value is relatively complicated. To avoid such a complication, it may be set so that the difference between the equivalent inductance value of the variable inductance circuit in the ON state of the secondary side switch element and the equivalent inductance value assuming that the both terminals of the secondary side inductance element are open, and the difference of the equivalent inductance value of the variable inductance circuit in the OFF state of the secondary side switch element and the equivalent inductance value assuming that the both terminals of the secondary side inductance element are open, are substantially equal to each other. This makes it possible to more easily design the variable inductance circuit capable of reducing the variation of Q.

Further, in the high-frequency IC for modulation and demodulation used for the WCDMA cellular phone, when the oscillation circuit according to the invention is applied as a VCO for generating a local oscillation signal to be synthesized with a transmission signal and a reception signal, the number of mounted VCOs can be reduced as the frequency variable range is wide. In addition, on-chip elements can be used as the inductance element and variable capacitance element that constitute the VCO. Thus, it is possible to avoid an increase of the number of external terminals and to reduce the chip size.

The following is a brief description of effects obtained by typical inventions disclosed herein.

That is, according to the invention, it is possible to realize an LC resonance type oscillation circuit with a wide frequency variable range with a small variation of Q and capable of reducing the chip size due to no external parts required, and a communication semiconductor circuit device (high-frequency IC) having the oscillation circuit.

### BRIEF DESCRIPTION OF THE DRAWINGS

FIGS. 1A and 1B are circuit diagrams each showing an example of a variable inductance circuit in a conventional variable inductance type of voltage controlled oscillator (VCO);

FIG. 2 is a characteristic diagram showing the relation between the frequency variable amount and the Q value in a voltage controlled oscillator (VCO) using the variable inductance circuit in FIGS. 1A, 1B and using a variable inductance circuit according to the present invention;

FIG. 3 is a circuit diagram showing a first embodiment of the voltage controlled oscillator (VCO) according to the invention;

FIG. 4 is a characteristic diagram showing the relation between a control voltage Vt and the frequency range in the oscillation circuit according to the embodiment;

FIG. 5 is a circuit diagram showing an equivalent circuit when switching the variable inductance circuit of the oscillation circuit according to the embodiment;

FIG. 6 is a characteristic diagram showing the relation between the frequency variable amount and the Q value when the frequency variable range is made uniform in the voltage control oscillation circuit (VCO) using the variable inductance circuit in FIGS. 1A, 1B and using the variable inductance circuit according to the invention;

FIG. 7 is a circuit diagram showing a second embodiment of the voltage controlled oscillator (VCO) according to the invention;

FIG. 8 is a circuit diagram showing a third embodiment of the voltage controlled oscillator (VCO) according to the invention;

FIG. 9 is a circuit diagram showing a fourth embodiment of the voltage controlled oscillator (VCO) according to the invention;

FIG. 10 is a top view showing an example of the layout of the elements constituting a variable inductance circuit on a semiconductor chip, for realizing the VCO according to the fourth embodiment as a semiconductor circuit device;

FIGS. 11A and 11B are cross-sectional views showing the cross-sectional configuration of the chip, taking along lines A-A and B-B in FIG. 10;

FIG. 12 is a block diagram showing a configuration example of a communication semiconductor circuit device (high-frequency IC) to which the oscillation circuit according to the embodiment is applied, and a wireless communication device using the semiconductor circuit device; and

FIG. 13 is a block diagram showing a configuration example of a GSM wireless communication device as another example of the communication semiconductor circuit device (high-frequency IC) to which the oscillation circuit according to the invention is applied and the wireless communication device using the semiconductor circuit device.

### DETAILED DESCRIPTION OF THE PREFERRED EMBODIMENTS

Next, embodiments of the present invention will be described with reference to accompanying drawings.

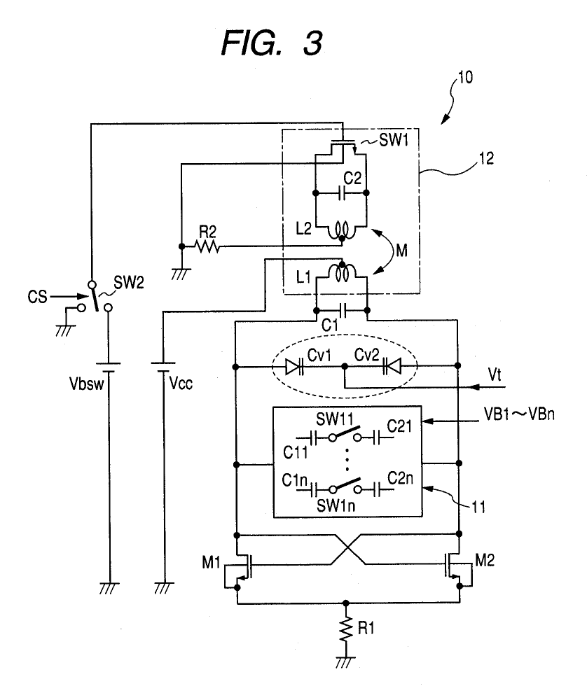

FIG. 3 shows a first embodiment of a voltage controlled oscillator (VCO) according to the invention. All elements constituting a circuit of this embodiment are on-chip elements. The VCO is formed as a semiconductor circuit device over a single semiconductor chip such as single-crystal silicon.

In the embodiment, a VCO 10 is a resonance type oscillation circuit having a pair of n-channel MOSFETs (Metal Oxide Semiconductor Field Effect Transistors) M1, M2 as negative resistances. The MOSFETs M1, M2 are connected to a common source and their gates and drains are cross connected to each other. A resistance R1 is connected between the common source of the MOSFETs M1, M2 and a ground point GND. Between the drains of the MOSFET M1, M2, variable capacitance elements Cv1, Cv2 including a capacitance array 11 and a varactor diode, a fixed capacitance C1, and an inductor L1 are connected in parallel to each other. A power source voltage terminal Vcc is connected to an intermediate node of the inductor L1.

Further, an inductor L2 is provided facing the inductor L1 and connected by mutual induction to the L1. Between both terminals of the inductor L2, a switch MOSFET SW1 and a capacitance element C2 are connected. A ground potential GND is applied to an intermediate node of the inductor L2. The ground potential GND is also applied to a back gate of the switch MOSFET SW1. A voltage Vbsw or the ground potential GND is applied to a gate terminal of the switch MOSFET SW1 by a selection switch SW2 controlled by a control signal CS, and thereby the SW1 is set to an ON state or an OFF state.

The capacitance array 11 is formed by capacitance C11-switch SW11-capacitance C21 that are serially connected between the drain terminals of the MOSFETs M1, M2, and also by C12-SW12-C22, . . . C1n-SW1n-C2n that are connected in parallel thereto. In the VCO of the embodiment, a control voltage Vt is applied from a loop filter of PLL, which will be described below, to a connection node NO of the variable capacitance elements Cv1, Cv2, where the oscillation frequency fvco is continuously changed.

On the other hand, band switching control signals VB1 to VBn are supplied from an automatic band selection circuit to switches SW11 to SW1n. It is configured so that the oscillation frequency is changed in stages (2n stages) by making the level of each of the VB1 to VBn high or low, respectively. Incidentally, the “n” is any positive integer number, and the number of steps to change the oscillation frequency fvco is increased as the “n” is made larger.

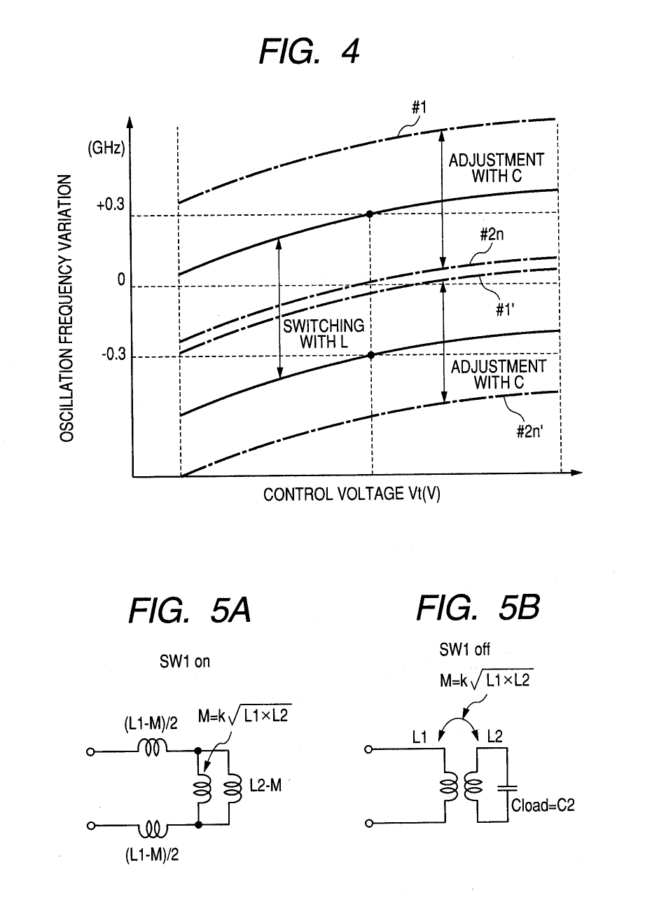

Further, the capacitances C11 and C12 have the same capacitance value. Similarly C1n and C2n, and C1n and C2n respectively have the same capacitance value. However, the capacitances C11, 12, . . . C1n are each set to have a weight equal to m-multiplied by 2 (where m is 0, 1, 2 . . . n−1). In accordance with the combination of the band switching control signals VB1 to VBn, a synthesized capacitance value C is changed in 2n steps. Thus, the VCO is designed to operate based on either of the frequency characteristics of the 2n bands #1 to #2n shown in FIG. 4.

When it is tried to widen the frequency range that the VCO should cover by only the change of the capacitance value of the varactor diode due to the control voltage Vt, the Vt-fvco characteristic is too precipitous. The sensitivity of the VCO, namely, the ratio between the frequency variation amount and the control voltage variation amount (Δf/ΔVt) increases, and then the VCO becomes susceptible to noise. In other words, the oscillation frequency of the VCO is largely changed only when a slight noise is superposed on the control voltage Vt. The VCO of the embodiment is designed to perform an oscillation control based on either of the 2n Vt-fvoc characteristic curves, through the change of the value of C in such a way that plural capacitance elements constituting an LC resonance circuit are provided in parallel to each other to switch the capacitance element to be connected in 2n steps by the band switching control signals VB1 to VBn.

Further, in the voltage controlled oscillator (VCO) of the embodiment, the inductance value seen from the inductor L1 side is changed by setting the switch MOSFET SW1 to the ON or OFF state. In other words, the variable inductance circuit 12 is formed by the inductors L1, L2, the switch MOSFET SW1 and the capacitance element C2. More specifically, the inductance value decreases when the switch MOSFET SW1 is turned to the ON state, and the inductance value increases when the switch MOSFET SW1 is turned to the OFF state. When the inductance value decreases, the oscillation frequency of the VCO becomes higher. When the inductance value increases, the oscillation frequency of the VCO becomes lower. The VCO is designed to operate based on either of the frequency characteristics of 2n bands #1 to #2n or #1′ to #2n′ shown in FIG. 4 in conjunction with the switching of the inductance value by the variable inductance circuit 12 and with the switching of the capacitance value by the capacitance array 11. In this way the variable range of the frequency is further widened.

Incidentally, the variable operation of the VCO frequency with the switching of the capacitance value in the capacitance array 11 is known as it is the same as that disclosed in JP-A-2004-159222. Thus, the detailed description will be omitted, and the variable operation of the frequency with the switching of the inductance value in the variable inductance circuit 12 will be described below.

FIG. 5A shows an equivalent circuit of the variable inductance circuit 12 in the ON state of the switch MOSFET SW1 within the inductance circuit 12 in the VCO of the embodiment of FIG. 3. FIG. 5B shows an equivalent circuit of the variable inductance circuit 12 in the OFF state of the switch MOSFET SW1.

An equivalent inductance Leq1 of the equivalent circuit of FIG. 5A, which shows the ON state of the switch MOSFET SW1 within the variable inductance circuit 12, is represented by the following equation (1):
Leq1=(1−k²)×L1 (1)
Here, as the range that the coupling coefficient k can take is 0<k<1, it is found that the equivalent inductance Leq1 is smaller than the value L1 in the case where the secondary side inductor L2 is not present, namely, the both terminals of the L2 are open.

The circuit in the OFF state of the switch MOSFET SW1 within the variable inductance circuit 12, as shown in FIG. 5B, is equivalent to the circuit with the capacitance C2 connected between the both terminals of the inductor L2 as a secondary side coil. An equivalent inductance Leq2 seen from the primary side of this circuit is represented by the following equation (2):
Leq2=L1+(ωM)²×C2/(1−ω²L2C2) (2)
where the mutual inductance is M and the coupling coefficient is k. Here, as M2=k2L1L2, the equation (2) is modified to the following equation (3):
Leq2=L1+(ωk)²×C2L1L2/(1−ω²L2C2) (3)
It is found that the equivalent inductance Leq2 can be made larger than the value L1 when the both terminals of the secondary side coil L2 are open, by appropriately selecting the constant value from the equations (2), (3).

In the VCO of the embodiment, it is set so that the oscillation frequency fvco(0)=3.8 GHz when the both terminals of the secondary side coil L2 are open, namely, k=0 and L=L1. Further, the values of the secondary side inductance L2 and capacitance C2 within the variable inductance circuit 12 are set so that the oscillation frequency fvco(1)=3.8+0.3 GHz when the switch MOSFET SW1 within the variable inductance circuit 12 is turned ON and the oscillation frequency fvco(2)=3.8-0.3 GHz when the SW1 is turned OFF.

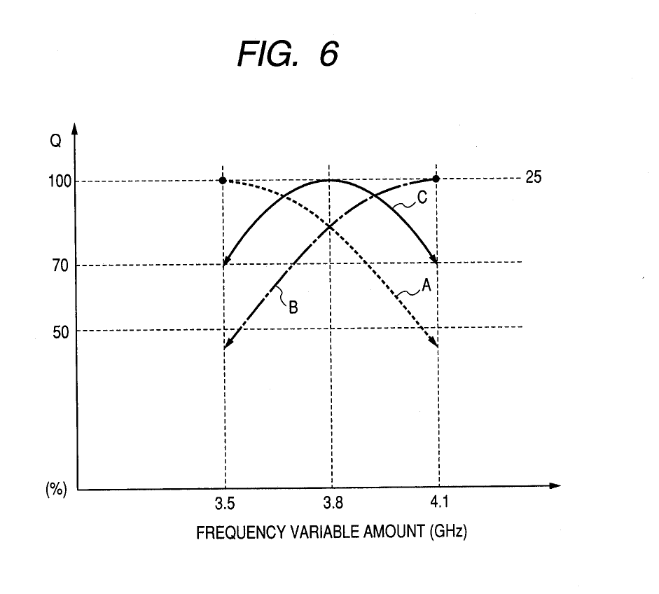

With such settings, as indicated by the solid line C in FIG. 6, it is possible to switch the oscillation frequency fvco to 4.1 GHz and 3.5 GHz by switching the inductance value of the variable inductance circuit 12. The following Table 1 shows the result obtained by a simulation of the Q value in the OFF state and ON state of the switch MOSFET SW1 within the variable inductance circuit 12 in the VCO designed as described above. Incidentally, the Q value is “25” when the both terminals of the secondary side coil L2 of the VCO are open, namely, k=0 and L=L1.

TABLE 1

| Frequency | | | Embodiment |
|---|---|---|---|
| 3.5 GHz | 25 | 13.08 | 17.71 |
| 4.1 GHz | 13.73 | 25 | 17.61 |

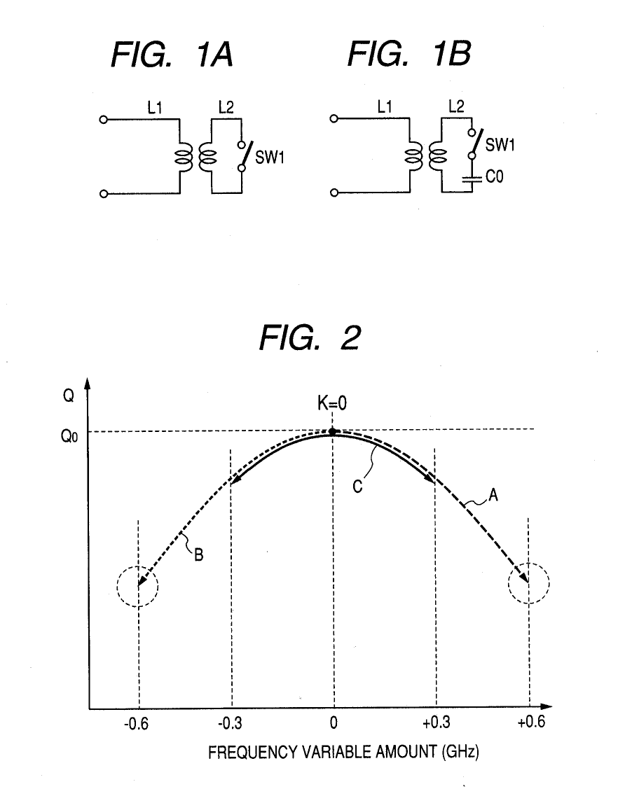

For comparison, Table 1 also shows the result of a simulation performed for the VCO having the configuration of the variable inductance circuit as shown in FIG. 1A and for the VCO having the configuration as shown in FIG. 1B. In Table 1, the numeric value of the column for FIG. 1A, as indicated by the dashed line A in FIG. 6, is the result of a simulation performed for the VCO having a frequency variable range of 0.6 GHz which is the same as in the embodiment with the oscillation frequency set to fvco(0)=3.5 GHz when the both terminals of the secondary side coil L2 are open, namely, k=0 and L=L1.

Further in Table 1, the numeric value of the column for FIG. 1B, as indicted by the dotted line B in FIG. 6, is the result of a simulation performed for the VCO having the frequency variable range of 0.6 GHz which is the same as in the embodiment with the oscillation frequency set to fvco(0)=4.1 GHz when the both terminals of the secondary side coil L2 are open, namely, k=0 and L=L1.

It is seen from Table 1 that in the VCO of the embodiment, when the oscillation frequency is changed by switching the inductance value of the variable inductance circuit 12, the Q values are 17.71 and 17.61 respectively where the reduction of Q is at most 30%. On the other hand, in the VCO of the configuration shown in FIG. 1A, the Q values are 25 and 13.73 respectively where the reduction of Q reaches 55%. Further, in the VCO of the configuration shown in FIG. 1B, the Q values are 25 and 13.08 respectively where the reduction of Q reaches 52%. Thus, it is found that when the embodiment is applied, the variation of the Q value of the VCO in the switching of the inductance value can be made smaller than the conventional VCO.

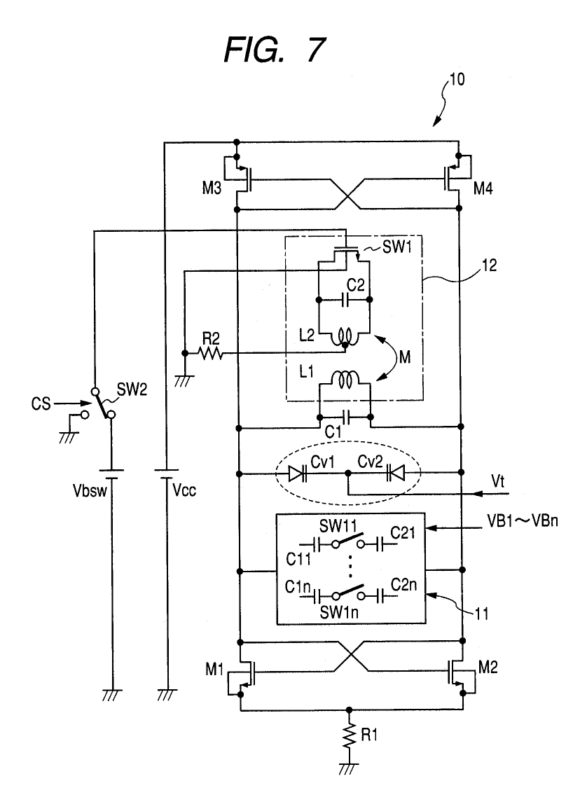

FIG. 7 shows a second embodiment of the VCO according to the invention. The VCO of this embodiment is formed as a CMOS circuit in such a way that a pair of P channel MOSFETs M3, M4 whose gates and drains are cross connected to each other, are provided between the power source terminal Vcc and the drain terminals of a pair of differential MOSFETs M1, M2 as negative resistances. The other configuration is the same as the VCO of the first embodiment. The VCO of this embodiment has an output amplitude smaller than the VCO of the first embodiment. However, there is an advantage that the power consumption can be reduced because the conductance of the negative resistance circuit is added as it is the CMOS circuit.

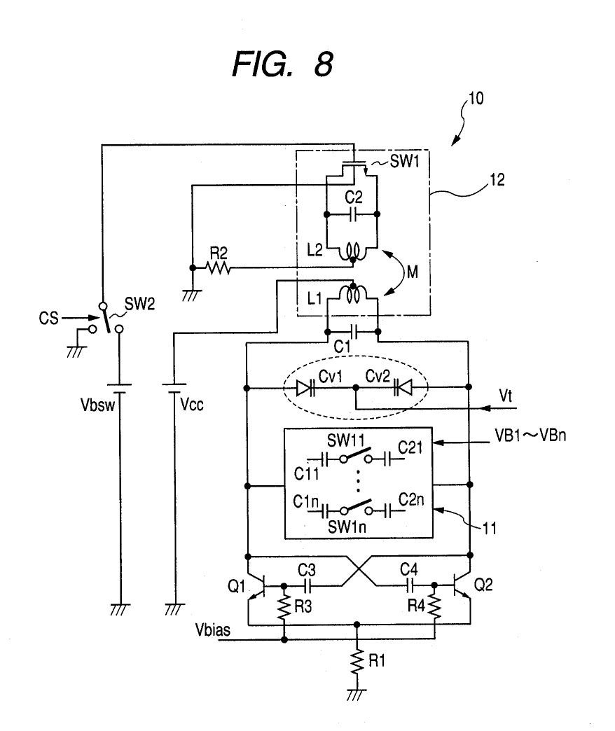

FIG. 8 shows a third embodiment of the VCO according to the invention. The VCO of this embodiment uses a pair of differential NPN bipolar transistors Q1, Q2 whose bases and collectors are cross connected to each other, in place of the pair of MOSFETs M1, M2 as negative resistances. Further, it is designed so that capacitances C3, C4 are connected between the bases and collectors in order to prevent the electric current from flowing into the bases, and that a bias voltage Vbias to be an operation point is given to the base terminals through resistances R3, R4. The other configuration is the same as the VCO of the first embodiment. Although the VCO of this embodiment has an output amplitude smaller than the VCO of the first embodiment, substantially the same effect as the VCO of the first embodiment can be achieved.

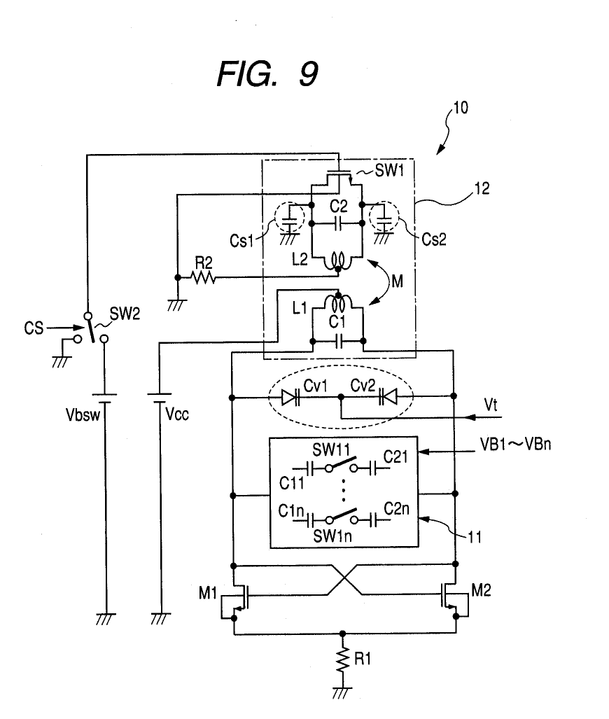

FIG. 9 shows a fourth embodiment of the VCO according to the invention. The VCO of this embodiment is designed so that as the switch MOSFET SW1 constituting the variable inductance circuit 12, parasitic capacitances Cs1, Cs2 connected to the sources and drains are actively used as the capacitance elements connected to the both terminals of the secondary side inductor L2.

By using the parasitic capacitances of the respective sources and drains of the MOSFET SW1, the proper size of the capacitance element C2 connected between the both terminals of the secondary side inductor L2 can be reduced. Further, by increasing the size of the switch MOSFET SW1, the ON resistance can be reduced. With this feature, it is possible to avoid reducing the equivalent inductance value, namely, the variation amount of the VCO oscillation frequency due to the ON resistance of the SW1, by reducing the parasitic resistances serially connected to the secondary side inductor L2.

Here, as a method of increasing the parasitic capacitances of the respective sources and drains of the MOSFET SW1, there may be considered a method of increasing the sizes of the source region and drain region in a direction orthogonal to the gate electrode, and a method of increasing the sizes in a direction parallel to the gate electrode. In order to achieve an effect to reduce the ON resistance of the SW1 at the same time, the method of increasing the sizes of the source region and drain region in the direction parallel to the gate electrode is desired.

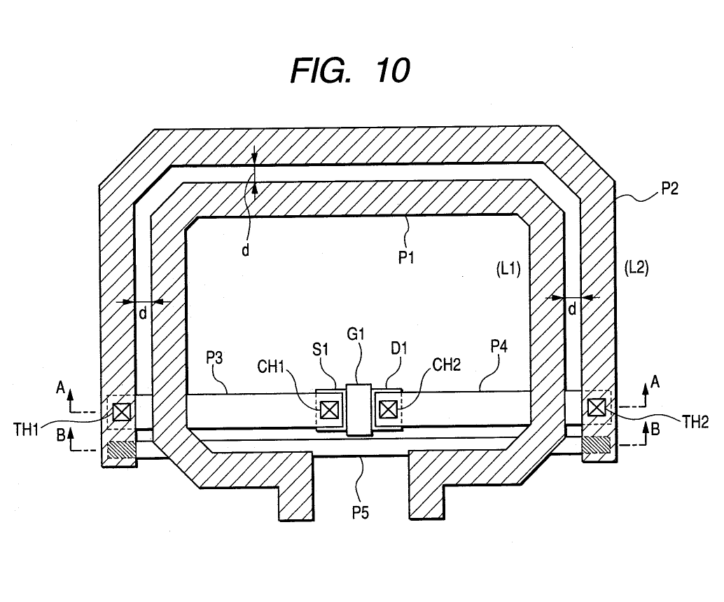

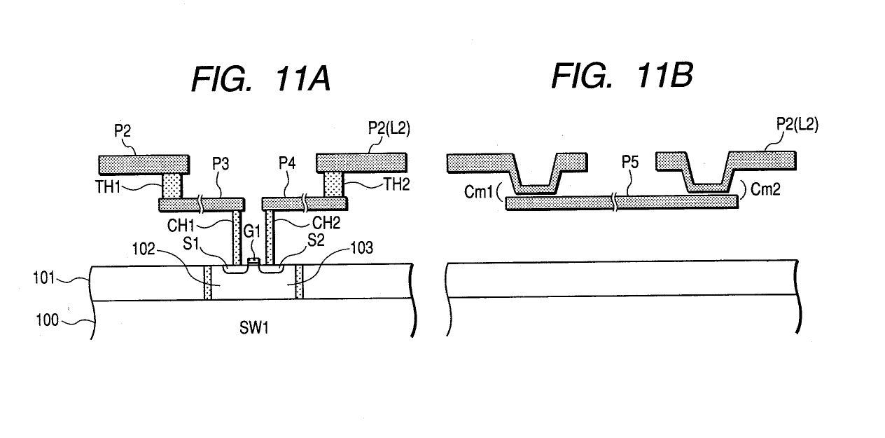

FIG. 10 shows an example of the layout of the elements constituting the variable inductance circuit 12 over a semiconductor chip, for realizing the VCO of the fourth embodiment as a semiconductor circuit device. FIGS. 11A and 11B show the sectional configuration of the chip, taking along lines A-A and B-B in FIG. 10.

In FIG. 10, denoted by reference symbol P1 is a conductive pattern to be the inductor L1 formed by a metal layer such as aluminum. A pattern P2 having a similar shape is disposed outside the pattern P1 with a relatively small distance d therebetween. The pattern P2 is a conductive pattern to be the secondary side inductor L2 formed by the same metal layer as the P1. Denoted by reference symbol G1 is a gate electrode of the switch MOSFET SW1 formed by a polysilicon layer. A source region S1 and a drain region D1, which are formed by a diffused layer, are disposed on the both sides of the gate electrode.

The source region S1 and the drain region D1 are electrically connected to the ends of the conductive pattern P2 to be the secondary side inductor L2, by wiring patterns P3, P4 each of which is formed by a metal layer different from the layers of the P1 and P2. Reference symbols CH1, CH2 denote contact holes for electrically connecting the source region S1 and drain region D1 respectively to the wiring patterns P3, P4. Reference symbols TH1, TH2 denote through holes for electrically connecting the wiring patterns P3, P4 and the conductive pattern P2 to be the secondary side inductor L2.

Although not specifically limited, in this embodiment, a conductive pattern P5 is disposed with the ends thereof facing the both ends of the conductive pattern P2 while being orthogonal to the P2, and as shown in FIG. 11B, MIM capacitances Cm1, Cm2 with an interlayer insulating film as a dielectric material are formed in the parts (indicated by hatching) where the conductive patterns P2 and P5 are overlapped. The MIM capacitances are used for the capacitance C2 constituting the variable inductance circuit 12. The pattern P5 can have the same metal layer as the wiring patterns P3, P4.

With the layout as described in the embodiment, the coupling coefficient k of the inductors L1 and L2, namely, the frequency range can be finely adjusted, by changing the distance d between the patterns P1 and P2, or by displacing the pattern P1 or P2 up or down in FIG. 10. Modification of either form of the patterns P1, P2 is necessary to entirely change the distance d between the P1 and P2. In the latter method of finely adjusting the frequency range by displacing the P1 or P2, there is an advantage that the adjustment can be extremely easy due to no pattern change required. Further, the conductive patterns P1 and P2 to be the inductors L1 and L2 are desirably formed on a top layer of the metal layer. The top layer of the metal layer can be made thicker than the other layers of the metal layer, so that the inductor having a higher Q can be formed through the use of the top layer of the metal layer where the resistance loss is small.

The MOSFET (SW1) is formed, as shown in FIG. 11A, within an island-shaped region 103 electrically separated from the periphery by a so-called U-groove isolation region 102 which is formed by digging a groove from the surface of an epitaxial layer 101 formed on a semiconductor substrate 100 and by filling an insulating material.

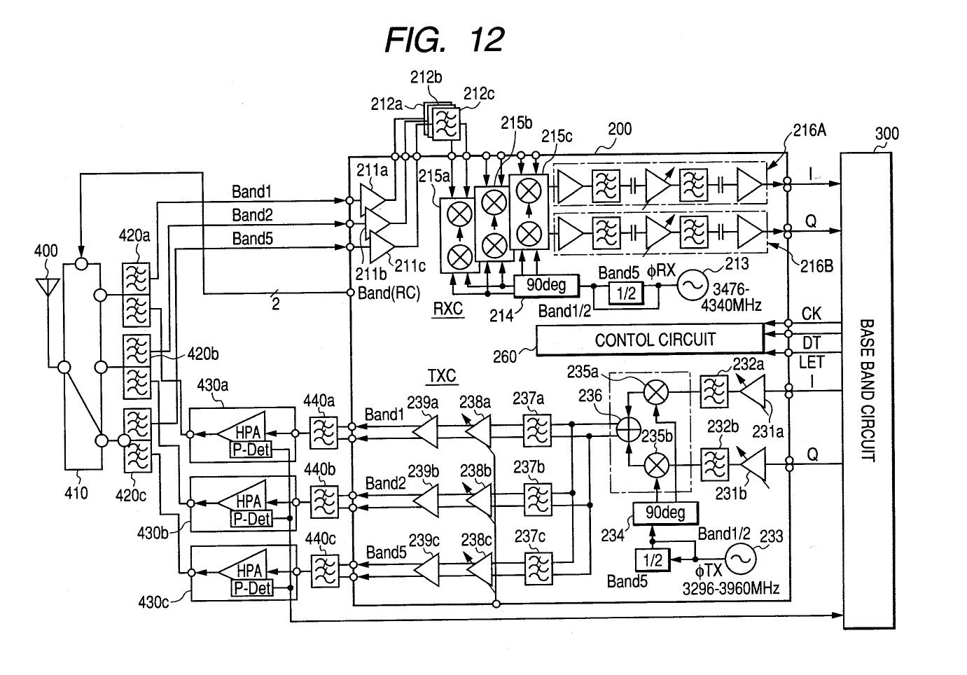

Next, the description will be made, with reference to FIG. 12, on an example of the entire configuration of the high-frequency IC to which the voltage controlled oscillator (VCO) of the above described embodiment is applied as a generation source of the local oscillation signal, and on the WCDMA wireless communication device using the high-frequency IC.

As shown in FIG. 12, the wireless communication device of this embodiment includes: an antenna 400 for transmitting/receiving signal waves; a band selection switch 410; duplexers (branching filters) 420a to 420c for separating a transmission signal and a reception signal; and high-frequency power amplitude circuits (power modules) 430a to 430c for amplifying the transmission signal. The wireless communication device further includes: a high-frequency IC 200 for demodulating the reception signal and modulating the transmission signal; band pass filters 440a to 440c for eliminating harmonics from the transmission signal; and a base band IC 300 for converting the transmission data to I and Q signals and for controlling the high-frequency IC 200. In the embodiment, the high-frequency IC 200 and the base band IC 300 are formed on a separate semiconductor chip as a semiconductor circuit device.

Although not specifically limited, the high-frequency IC 200 of this embodiment is configured to be able to modulate/demodulate signals of three frequency bands. The high-frequency IC 200 of the embodiment includes a reception system circuit RXC, a transmission system circuit TXC, and a control system circuit including circuits common to the other transmission/reception systems, such as a control circuit and a clock generation circuit.

The reception system circuit RXC includes: low noise amplifiers 211a to 211c for amplifying reception signals of frequency bands 2110 to 2170 MHz, 1930 to 1990 MHz, and 869 to 894 MHz, respectively; band pass filters 212a to 212c formed by a SAW filter and the like for eliminating unnecessary waves from the reception signal; a frequency division phase shift circuit 214 for frequency-dividing a local oscillation signal φRX generated in a reception side oscillation circuit (RxVCO) 213 to generate orthogonal signals whose phases are shifted by 90 degrees from each other; mixer circuits 215a to 215c for demodulating and down-converting the I and Q signals by mixing the reception signal with the orthogonal signals generated in the frequency division phase shift circuit 214; and high gain amplifiers 216A, 216B common to each of the frequency bands to amplify the demodulated I and Q signals which are then output to the base band IC 300. The band pass filters 212a to 212c are formed by external elements. The high gain amplifiers 216A, 216B each have a configuration that plural low pass filters and plural gain control amplifiers are alternately connected in a series form, thereby to amplify the demodulated I and Q signals to a predetermined amplification level.

The transmission system circuit TXC includes: variable gain amplifiers 231a, 231b for amplifying the I and Q signals supplied from the base band IC 300; low pass filters 232a, 232b; a transmission side oscillation circuit (TXVCO) 233 for generating a transmission local oscillation signal φTX; a frequency division phase shift circuit 234 for frequency-diving the oscillation signal φTX generated in the oscillation circuit 233 to generate orthogonal signals whose phases are shifted by 90 degrees from each other; an orthogonal modulation circuit formed by mixers 235a, 235b for modulating the generated orthogonal signals through the I and Q signals supplied from the base band circuit 300; an accumulator 236 for synthesizing the modulated signals; low pass filters 237a to 237c provided for each of the transmission frequency bands; variable gain amplifiers 238a to 238c for amplifying the transmission signals of each of the frequency bands; and last stage buffer amplifiers 239a to 239c.

The power modules 430a to 430c each have a detection circuit (P-DET) for detecting the size of the output power. The detected voltage is passed to the base band IC 300. Depending on the received detected voltage and an output request level from a base station, the base band IC 300 transmits the gain setting values of the variable gain amplifiers 231a, 231b and 238a to 238c, to the control circuit 260. Then the gains of each of the amplifiers are controlled by the control circuit 260.

Further, the control circuit 260 for controlling the entire chip is provided on the chip of the high-frequency IC 200 of this embodiment. The control circuit 260 is supplied with signals such as a clock signal CLK for synchronization, a data signal DT, and a load enable signal LEN as a control signal, from a base band LSI 300 to the high-frequency IC 200. When the load enable signal LEN is asserted to an effective level, the control circuit 260 synchronizes a data signal DT transmitted from the base band IC 300 with the clock signal CLK, taking the synchronized signal in series to set in the control resister, and generating control signals to the circuits within the IC in accordance with the set contents. The data signal DT is transmitted in a serial fashion although not specifically limited thereto. The base band IC 300 is formed by a microprocessor and the like. The data signal DT contains a command given from the base band IC 300 to the high-frequency IC 200.

The oscillation circuit of the above described embodiment is used as the oscillation circuits 213 and 233 within the high-frequency IC 200. However, the oscillation circuits 213 and 233 have different oscillation frequency ranges, each using a different value for the inductance elements L1, L2. For example, the value for the L1, L2 of the reception side oscillation circuit 213 is set to about 500 pH, and the value for the L1, L2 of the transmission side oscillation circuit 233 is set to about 530 pH.

In the multi-band wireless communication device of the embodiment, the transmission/reception frequency is switched in such a way that the control circuit 260 changes the oscillation frequencies of the oscillation circuits 213 and 233 by a command from the base band IC 300 upon transmission and reception, depending on the band to be used. Further, an inductance switch control signal CS is supplied from the control circuit 260 to the oscillation circuits 213 and 233, depending on the frequency band to be used.

The oscillation frequencies of the oscillation circuits 213 and 233 are set to different values even with the same frequency band. The oscillation frequency of the reception side oscillation circuit (RxVCO) 213 is set to 4220 to 4340 MHz for Band 1, 3860 to 3980 MHz for Band 2, and 3476 to 3576 MHz for Band 5. The oscillation frequency fRX set for Band 5 is frequency-divided into one quarter. The oscillation frequencies fRX set for Band 1 and Band2 are frequency-divided into one half and supplied to the mixers 215a to 215c.

The oscillation frequency of the transmission side oscillation circuit (TXVCO) 233 is set to 3840 to 3960 MHz for Band 1, 3700 to 3820 MHz for Band 2, and 3296 to 3396 MHz for Band 5. The oscillation frequency fTX set for Band 5 is frequency-divided into one quarter. The oscillation frequencies set for Band 1 and Band 2 are frequency-divided into one half and supplied to the mixers 235a, 235b.

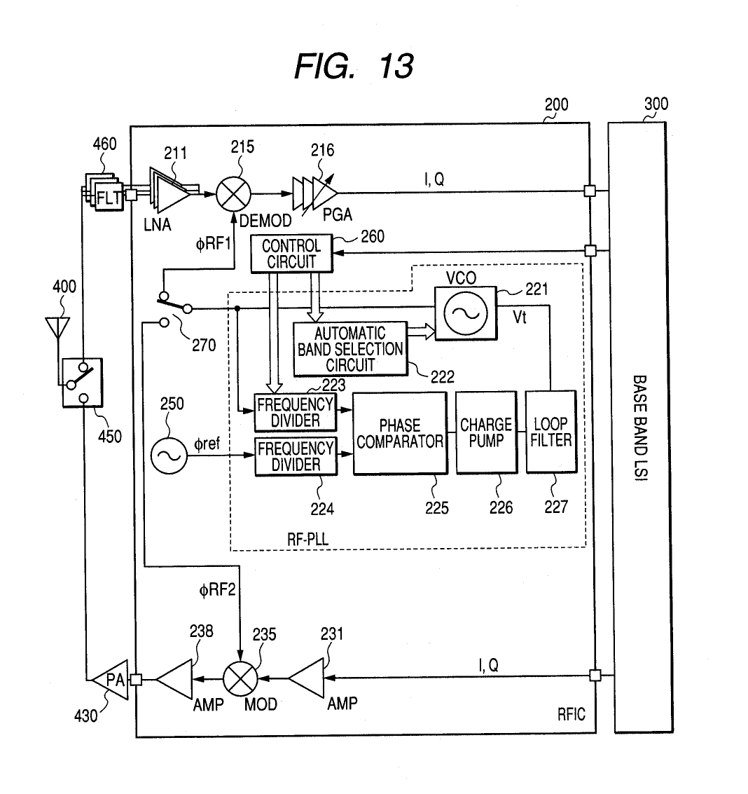

FIG. 13 is a block diagram showing a configuration example of a triple-band wireless communication device capable of handling three types of communication systems, GSM, DCS and PCS, as another example of the communication semiconductor circuit device (high-frequency IC) to which the oscillation circuit according to the invention is applied and of the wireless communication device using the semiconductor circuit device.

The wireless communication device shown in FIG. 13 includes: an antenna 400 for transmitting and receiving signal waves; a switch 450 for switching transmission and reception; a high-frequency filter 460 formed by the SAW filter and the like for eliminating unnecessary waves from the reception signal; a power amplifier 430 for amplifying the transmission signal; a high-frequency IC 200 for demodulating the reception signal and modulating the transmission signal; and a base band IC 300. Incidentally, in FIG. 13, the reception system circuit RXC and the transmission system circuit TXC are simplified compared to those in FIG. 12 because of space limitations.

The reception system circuit includes: a low noise amplifier 211 for amplifying the reception signal; a mixer 215 for performing demodulation and down-conversion by synthesizing an oscillation signal φFR1 generated in the oscillation circuit VCO with the reception signal amplified in the low noise amplifier 211; and a high gain amplifier (PGA) 216 for amplifying the demodulated I and Q signals which are then output to the base band IC 300. The low noise amplifier 210 and the high-frequency filter 460 are provided corresponding to each of the frequency bands GSM and DCS and PCS.

The transmission system circuit includes: an amplifier 231 for amplifying the I and Q signals supplied from the base band IC 300; a mixer 235 for performing modulation and up-conversion by synthesizing the amplified I and Q signals with an oscillation signal φRF2 generated in the oscillation circuit VCO; and an amplifier 238 for amplifying the modulated signal. The mixer 235 is a circuit similar to an orthogonal modulation circuit formed by the mixers 235a, 235b and the accumulator 236, which are shown in FIG. 12.

In the embodiment, the RF-PLL for generating the high-frequency signal φRF1 to be synthesized with the reception signal in the mixer 215 and the FR-PLL for generating φRF2 to be synthesized with the transmission signal in the mixer 235 are shared with each other. The oscillation circuit described in the above embodiment can be used as the VCOs within the PLL. In the WCDMA wireless communication device where the transmission and reception are performed at the same time, the reception side oscillation circuit and the transmission side oscillation circuit are necessary. However, in the GSM wireless communication device where the transmission and reception are performed in a time sharing manner, the reception oscillation circuit and the transmission oscillation circuit can be made common to each other.

The GSM uses the 925 to 960 MHz band, the DCS uses the 1805 to 1880 MHz band, and the PCS uses the 1930 to 1990 MHz band, respectively. For example, the variable inductance circuit within the oscillation circuit of the embodiment is switched between the GSM, and the DCS or PCS. Alternatively, it may be configured to use the GSM signal through one more frequency division steps than the case of the DCS by switching the variable inductance circuit between the GSM or DCS, and PCS.

The oscillation signal φRF generated in the VCO 221 is supplied to either the mixer 215 or 235 by a switch 270 which is selected depending on the transmission mode or the reception mode. To be more accurate, the φFR is supplied to either of the frequency division phase shift circuits not shown herein (see FIG. 12), which are provided corresponding to the mixers 215 and 235. The switch 270 is switched by the control signal from the control circuit 260.

The RF-PLL includes: a VCO 221; an automatic band selection circuit 222 for selecting a band that the VCO uses; a variable frequency divider 223 for frequency dividing the oscillation signal generated in the VCO 221; and a frequency divider 224 for frequency dividing a reference clock φref from a reference oscillation circuit 250. The RF-PLL further includes: a phase comparator 225 for comparing the phases of the signals frequency divided in the frequency dividers 223 and 224; a charge pump 226 for generating a voltage corresponding to the phase difference; and loop filter 227. The charged voltage of the loop filter 227 is supplied to the VCO 221 as the oscillation control voltage Vt.

The control circuit 260 switches the frequency of the VCO 221 within the RF-PLL. The control circuit 260 is provided with a control register, a data register and the like. The oscillation frequency (frequency division ratio) is set to the registers based on the signal from the base band IC 300. Then the value set in the registers is supplied to a register within the automatic band selection circuit 222 and to the variable frequency division circuit 223 in the RF-PLL. Along with this operation, oscillation frequency switch control signals (VB1 to VBn and CS in FIG. 3) are supplied from the control circuit 260 to the automatic band selection circuit 222 based on an instruction (command code, etc.) from the base band IC 300.

The description has been made in FIG. 13 taking an example of the high-frequency IC whose transmission system circuit is a direct up-conversion system. However, the oscillation circuit according to the invention is also applicable to the high-frequency IC whose transmission system circuit is a so-called offset PLL system using the signal of an intermediate frequency. In this case, it may be configured to frequency divide the oscillation signal generated in the high-frequency oscillation circuit common to the transmission system and the reception system to generate an intermediate frequency signal which is then supplied to the transmission system circuit.

The invention accomplished by the inventors has been described in detail based on the embodiments, but it is to be understood that the present invention is not limited to the embodiments. For example, the forgoing embodiments have been described in connection with the case where the set of secondary side inductor L2 and capacitance C2 and switch MOSFET SW1 is provided facing the single inductor L1 connected between the drain terminals of the pair of MOSFETs M1, M2 as negative resistances. However, the present invention is not limited to such a configuration, and may be configured so that inductors are provided between the power voltage terminal Vcc and each of the drain terminals of a pair of MOSFETs M1, M2, and that the secondary side inductor L2 and the capacitance C2 and switch MOSFET SW1 are provided facing each of the inductors, in other words, two sets of variable inductance circuits are provided.

Further, the forging embodiments have been described in connection with the case of providing the variable inductance circuit, which is configured to be able to take two equivalent inductance values represented by the equations (1) and (2) with the set of secondary side inductor L2 and capacitance C2 and switch MOSFET SW1 provided facing the primary side inductor L1. However, the invention is not limited thereto, and may be configured so that the equivalent inductance value can be switched in three or more steps by providing two or more sets of the secondary side inductor L2 and capacitance C2 and switch MOSFET SW1.

As an example of a way to place the secondary side inductor for realizing such a configuration, for example, in the layout of FIG. 10, it can be considered a method that conductive patterns, each constituting a secondary side inductor, are placed outside and inside the conductive pattern constituting the primary side inductor L1. Alternatively, the conductive pattern to be the secondary side inductor may be placed above or below the conductive pattern constituting the primary side inductor L1. The both conductive patterns are formed by different conductive layers.

Further in the fourth embodiment, there has been shown that the parts except the variable inductance circuit 12 are the same as the VCO of the first embodiment. However, the fourth embodiment may be combined with the second embodiment or third embodiment. Further, the capacitance array 11 can be omitted in the VCO used for the system where fine switching of band is not necessary, such as among the bands #1 to #2n, which has been described in the embodiment. The varactor diodes Cv1, Cv2 can be omitted unless the VCO is used for the PLL circuit.

The above description has mainly focused on an application of the present invention made by the inventors to the VCO included in the high-frequency IC used for the wireless communication device, such as a cellular phone, a field of applications which serves as the background of the invention. However, it is to be understood that the present invention is not limited thereto, and may be used for a mixer circuit using the resonance circuit as a load circuit of the Gilbert cell circuit.

What is claimed is:

1. An oscillation circuit that can take an oscillation output of different frequencies, the oscillation circuit comprising a variable inductance circuit including:
a first inductance element; and
a second inductance element connected by mutual induction to the first inductance element,
the variable inductance circuit capable of taking an inductance value which is 1 or more and smaller than an equivalent value assuming that both terminals of the second inductance element are open, or capable of taking an inductance value which is 1 or more and larger than an equivalent value assuming that the both terminals of the second inductance element are open.

2. An oscillation circuit that can take an oscillation output of different frequencies, the oscillation circuit comprising a variable inductance circuit including:
a first inductance element; and
a second inductance element connected by mutual induction to the first inductance element,
the variable inductance circuit capable of taking a first inductance value smaller than an equivalent value assuming that both terminals of the second inductance element are open, or a second inductance value larger than an equivalent value assuming that the both terminals of the second inductance element are open.

3. The oscillation circuit according to claim 2,
wherein the variable inductance circuit comprises a switch element connected between the both terminals of the second inductance element,
in accordance with an ON or OFF state of the switch element, the variable inductance circuit taking a first state where the both terminals of the second terminal are short-circuited, or taking a second state where a capacitive load is connected between the both terminals of the second inductance element, and
wherein the equivalent inductance value varies between the first state and the second state.

4. The oscillation circuit according to claim 3,
wherein the switch element is a MOSFET, and
wherein the variable inductance circuit uses a capacitance parasitic on a source and a drain of the MOSFET serving as the switch element, as the capacitive load.

5. The oscillation circuit according to claim 3,
wherein the variable inductance circuit comprises a capacitance element connected to the switch element in a parallel fashion.

6. The oscillation circuit according to claim 2, further comprising a negative resistance circuit connected to the first inductance element.

7. The oscillation circuit according to claim 2,
wherein a constant value of the variable inductance circuit is set so that a Q value of a tank circuit including the negative resistance circuit and the variable inductance circuit substantially is substantially equal in the ON and OFF states of the switch element.

8. The oscillation circuit according to claim 2,
wherein a difference between the first inductance value and the equivalent inductance value assuming that the both terminals of the second inductance element are open, is set substantially equal to a difference between the second inductance value and the equivalent inductance value assuming that the both terminals thereof are open.

9. The oscillation circuit according to claim 6,
wherein the negative resistance circuit is:
a differential circuit including a pair of MOSFETs whose gate terminals and drain terminals are cross connected and source terminals thereof are connected to each other,
a CMOS differential circuit including: a pair of P-channel MOSFETs whose gate terminals and drain terminals are cross connected and source terminals thereof are connected to each other; and a pair of N-channel MOSFETs whose gate terminals and drain terminals are cross connected and source terminals thereof are connected to each other, or
a differential circuit including a pair of bipolar transistors whose base terminals and collector terminals are cross connected and emitter terminals thereof are connected to each other.

10. The oscillation circuit according to claim 9,
wherein a variable capacitance circuit is connected between the drain terminals of the pair of MOSFETs constituting the differential circuit or between the collector terminals of the pair of bipolar transistors constituting the differential circuit,
the variable capacitance circuit including a plurality of fixed capacitance elements and a plurality of switch elements serially connected to each of the fixed capacitance elements.

11. The oscillation circuit according to claim 9,
wherein a variable capacitance element is connected between the drain terminals of the pair of MOSFETs constituting the differential circuit or between the collector terminals of the pair of bipolar transistors constituting the differential circuit.

12. A semiconductor circuit device comprising the oscillation circuit according to claim 3 formed over a semiconductor substrate,
wherein the first inductance element and the second inductance element are formed by patterns which are the same conductive layers disposed in a concentric manner,
wherein the switch element is formed over a surface of the semiconductor substrate inside the pattern of the conductive layer to be the first inductance element, and
wherein MIN capacitances to be capacitive loads are formed at both ends of the pattern of the conductive layer to be the second inductance element.

13. A communication semiconductor circuit device comprising:
the oscillation circuit according to claim 1; and
a demodulation circuit for demodulating a reception signal,
wherein the oscillation circuit is used as a circuit for generating a high-frequency signal used for demodulation in the demodulation circuit.

14. A communication semiconductor circuit device comprising:
the oscillation circuit according to claim 1; and
a modulation circuit for modulating a transmission signal,
wherein the oscillation circuit is used as a circuit for generating a high-frequency signal used for modulation in the modulation circuit.

15. A resonance circuit having a first inductance element, a capacitance element and a second inductance element, connected by mutual induction to the first inductance element, the resonance circuit comprising:
a variable inductance circuit capable of taking a first inductance value smaller than an equivalent inductance value assuming that the both terminals of the second inductance element are open, or a second inductance value larger than an equivalent inductance value assuming that the both terminals of the second inductance element are open.

16. The resonance circuit according to claim 15,
wherein the variable inductance circuit comprises a switch element connected between the both terminals of the second inductance element,
in accordance with an ON or OFF state of the switch element, the variable inductance circuit taking a first state where the both terminals of the inductance element are short-circuited, or a second state where a capacitive load is connected between the both terminals of the second inductance element, and
wherein the equivalent inductance value varies between the first state and the second state.
